(19) United States
(12) Patent Application Publication
(10) Pub. No.: US 2017/0365605 A1
(43) Pub. Date: Dec. 21, 2017

(54) NON-VOLATILE SCHOTTKY BARRIER FIELD EFFECT TRANSISTOR

(71) Applicant: Western Digital Technologies, Inc., Irvine, CA (US)

(72) Inventor: Daniel BEDAU, San Jose, CA (US)

(73) Assignee: HGST Netherlands B.V.

(21) Appl. No.: 15/184,831

(22) Filed: Jun. 16, 2016

(51) Int. Cl. H01L 27/105; H01L 29/47; H01L 29/24; H01L 29/08; H01L 29/06; H01L 29/80; H01L 27/095

(52) U.S. Cl. CPC H01L 27/1052; H01L 29/806; H01L 29/47; H01L 27/095; H01L 29/0891; H01L 29/0649; H01L 29/24

(57) ABSTRACT

The present disclosure generally relates to an apparatus for high density memory with integrated logic. A three terminal ReRAM device, which includes a p-n junction and a Schottky barrier, that can switch from a low resistive state to a high resistive state is provided. The Schottky transistor memory device includes a source region, a drain region, a first p-type or n-type oxide layer disposed between the source and drain regions, a second p-type or n-type oxide layer, and a gate electrode. As voltage is applied to the gate electrode, the Schottky barrier breaks down, leading to the formation of a filament. The filament is non-volatile and short-circuits the reverse-biased barrier, keeping the device in a low resistance state. Removing the filament by reversing the polarity of the voltage switches the device back to a high resistance state, allowing for the memory state to be readout through the gate electrode.

### BACKGROUND OF THE DISCLOSURE

### Field of the Disclosure

Embodiments of the present disclosure generally relate to a non-volatile memory device, specifically a resistive random-access memory (ReRAM) device.

### Description of the Related Art

Non-volatile memory is computer memory capable of retaining stored information even after having been power cycled. Non-volatile memory is becoming more popular because of its small size/high density, low power consumption, fast read and write rates, and retention. Flash memory is a common type of non-volatile memory because of its high density and low fabrication costs. Flash memory is a transistor-based memory device that uses multiple gates per transistor and quantum tunneling for storing information on its memory device. However, flash memory uses a block-access architecture that can result in long access, erase, and write times. Flash memory also suffers from low endurance, high power consumption, and scaling limitations.

Storage demand and the constantly increasing speed of electronic devices require new improvements for non-volatile memory. New types of memory, such as resistive random access memory (ReRAM), are being developed as flash memory replacements to meet these demands. Resistive memories refer to technology that uses varying cell resistance to store information. In order to switch a ReRAM cell, an external voltage with specific polarity, magnitude, and duration is applied. ReRAM devices are two terminal cells that always require an external select device. Thus, there is a need in the art for an improved ReRAM memory device.

### SUMMARY OF THE DISCLOSURE

The present disclosure generally relates to an apparatus for high density memory with integrated logic. A three terminal ReRAM device, which includes a p-n junction and a Schottky barrier, that can switch from a low resistive state to a high resistive state is provided. The Schottky transistor memory device includes a source region, a drain region, a first p-type or n-type oxide layer disposed between the source and drain regions, a second layer such as second p-type, n-type layer or gate dielectric, and a gate electrode. The second layer electrically insulates the oxide layer from the gate electrode. If the second layer is a p-type or n-type layer, a rectifying junction is formed at the interface between the second layer and the first p-type or n-type oxide layer. As voltage is applied to the gate electrode, the Schottky barrier breaks down, leading to the formation of a filament. The filament is non-volatile and short-circuits the reverse-biased barrier, keeping the device in a low resistance state. Removing the filament by reversing the polarity of the voltage switches the device back to a high resistance state, allowing for the memory state to be readout through the gate electrode.

In one embodiment, a Schottky transistor memory device comprises an insulating layer, a source region disposed on the insulating layer, a drain region disposed on the insulating layer, a first p-type or n-type oxide material layer disposed on the insulating layer in between the source region and the drain region, and a second p-type or n-type oxide material or gate dielectric layer disposed on the first p-type or n-type oxide material layer. A p-n junction is formed between the first p-type or n-type material layer and the second p-type or n-type oxide material layer. A gate electrode is disposed on the second p-type or n-type oxide material layer or gate oxide.

In another embodiment, a Schottky transistor memory device comprises an insulating layer, a source region disposed on the insulating layer, a drain region disposed on the insulating layer, a first p-type or n-type oxide material layer disposed on the insulating layer in between the source region and the drain region, and a second p-type or n-type oxide material layer disposed on the first p-type or n-type oxide material layer. A p-n junction is formed between the first p-type or n-type material layer and the second p-type or n-type oxide material layer. A gate electrode is disposed on the second p-type or n-type oxide material layer, and a conductive anodic filament extending from the drain region to the first p-type or n-type oxide material layer.

In another embodiment, a memory array comprising one or more Schottky transistor memory devices, at least one of the devices comprising an insulating layer, a source region disposed on the insulating layer, a drain region disposed on the insulating layer, a first p-type or n-type oxide material layer disposed on the insulating layer in between the source region and the drain region, and a second p-type or n-type oxide material layer disposed on the first p-type or n-type oxide material layer. A p-n junction is formed between the first p-type or n-type material layer and the second p-type or n-type oxide material layer. A gate electrode is disposed on the second p-type or n-type oxide material layer, and a conductive anodic filament extending from the drain region to the first p-type or n-type oxide material layer.

In another embodiment, a Schottky transistor memory device comprises an insulating layer, a source region disposed on the insulating layer, a drain region disposed on the insulating layer, a p-type or n-type oxide material layer disposed on the insulating layer in between the source region and the drain region, and a dielectric material disposed on the p-type or n-type oxide material layer. A gate electrode is disposed on the dielectric material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A shows a schematic illustration of a Schottky transistor memory device according to one embodiment.

FIG. 1B shows a schematic illustration of the Schottky transistor memory device of FIG. 1A after applying voltage.

FIG. 1C shows a schematic illustration of the Schottky transistor memory device of FIG. 1B after a reverse voltage is applied.

FIG. 1D shows a schematic illustration of a Schottky transistor device according to another embodiment.

FIG. 2 shows a schematic illustration of a memory array including one or more Schottky transistor memory devices.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to an apparatus for high density memory with integrated logic. A three terminal ReRAM device, which includes a p-n junction and a Schottky barrier, that can switch from a low resistive state to a high resistive state is provided. The Schottky transistor memory device includes a source region, a drain region, a first p-type or n-type oxide layer disposed between the source and drain regions, a second p-type or n-type oxide or dielectric layer, and a gate electrode. As voltage is applied to the gate electrode, the Schottky barrier breaks down, leading to the formation of a filament. The filament is non-volatile and short-circuits the reverse-biased barrier, keeping the device in a low resistance state. Removing the filament by reversing the polarity of the voltage switches the device back to a high resistance state, allowing for the memory state to be readout through the gate electrode.

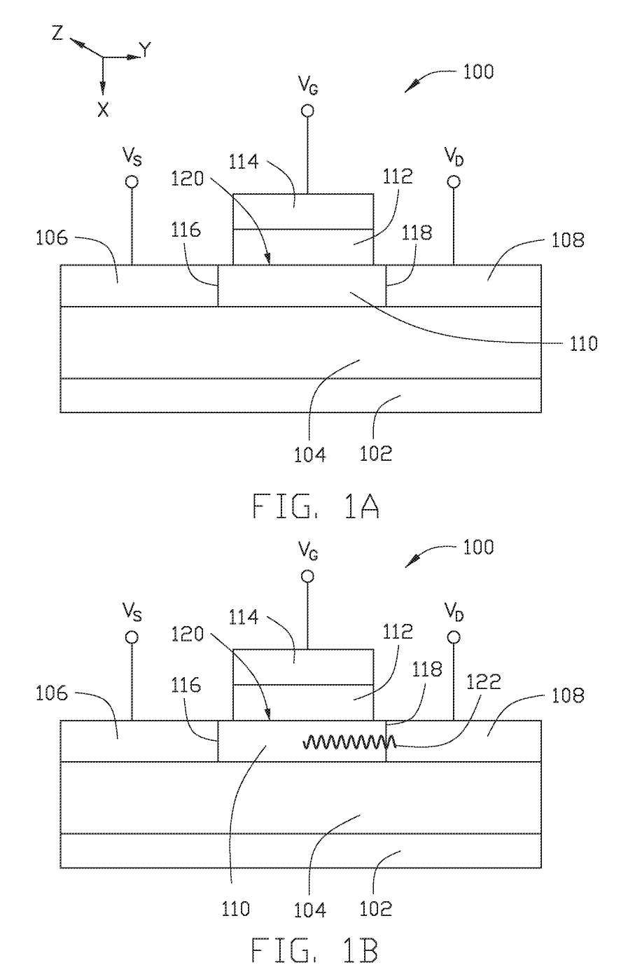

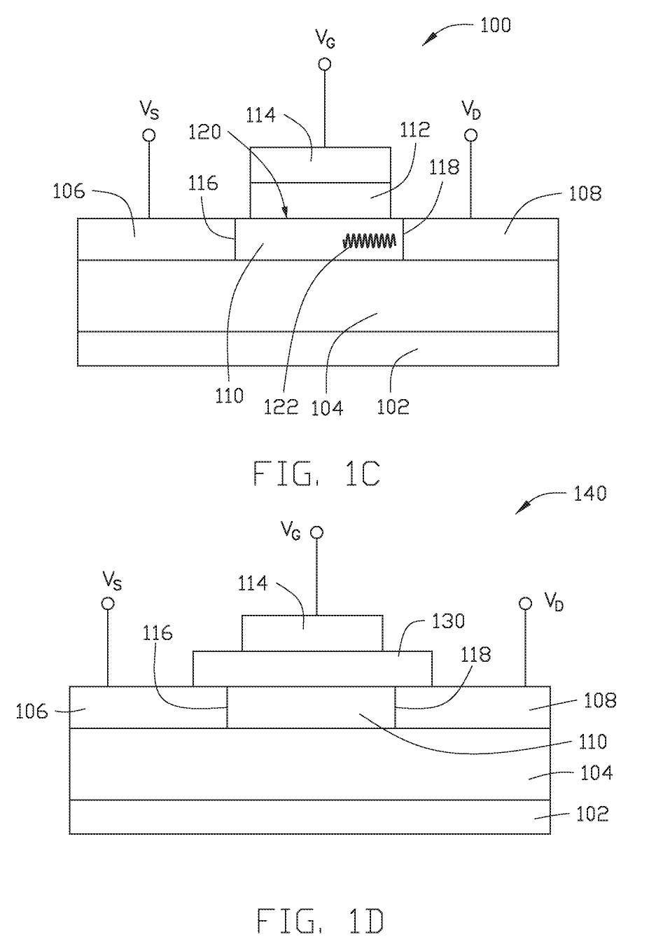

FIG. 1A shows a schematic illustration of a Schottky transistor memory device 100 according to one embodiment. The Schottky transistor memory device 100 may be a three terminal ReRAM device and/or a field effect transistor. The Schottky transistor memory device 100 may include a substrate 102, and an insulating layer 104 disposed on the substrate 102. A source region 106 and a drain region 108 may be disposed on the insulating layer 104. The source region 106 is not in contact with the drain region 108. A first p-type or n-type (p/n-type) oxide layer 110 may be disposed between the source region 106 and the drain region 108. The first p/n-type oxide layer 110 may be in contact with both the source region 106 and the drain region 108. A second layer 112, which may comprise a p-type or n-type oxide layer, may be disposed on the first p/n-type oxide layer 110. A gate electrode 114 may be disposed on the second layer 112. The second layer 112 is in contact with only the first p/n-type oxide layer 110 and the gate electrode 114. The second layer 112 is not in contact with either the source region 106 or the drain region 108, and thus, the second p/n-type oxide layer 112 has a smaller width in the x-direction than the first p/n-type oxide layer 110. In one embodiment, the gate electrode 114 extends laterally substantially the same distance as the second layer 112. In another embodiment, the second layer 112 extends laterally a greater distance than the gate electrode 114. In another embodiment, the second layer 112 may be disposed lateral the gate electrode 114 and may extend the height of the gate electrode 114.

In one embodiment, the insulating layer 104 comprises silicon dioxide (SiO₂). It is to be understood that other materials are contemplated as well, such as silicon nitride and silicon oxynitride. The gate electrode 114 may be polycrystalline silicon. The source region 106 and the drain region 108 may comprise a metal, such as platinum, ruthenium, or nickel. Additionally, the source region 106 and the drain region 108 may be a silicide selected from the group including but not limited to the following: platinum silicide (PtSi), nickel silicide (NiSi), sodium silicide (Na₂Si), magnesium silicide (Mg₂Si), titanium silicide (TiSi₂) or tungsten silicide (WSi₂). The source region 106 may be comprised of different materials than the drain region 108.

The first p/n-type oxide layer 110 may comprise a material that can be either p-type or n-type. The first p/n-type oxide layer 110 may be comprised of the same material as the second layer 112 in the case where a rectifying junction is formed between the first and second layers 110, 112. The first p/n-type oxide layer 110 and the second layer 112 may be comprised of the different materials if a heterojunction is formed. The first p/n-type oxide layer 110 and the second layer 112 may be a ReRAM material such as an oxide selected from the group including, but not limited to, the following: hafnium oxide (HfO₂), titanium oxide (TiO₂), tantalum oxide (TaO₂), indium-tin-oxide (ITO), zinc oxide (ZnO), vanadium oxide (VO₂), tungsten oxide (WO₂), zirconium oxide (ZrO₂), copper oxide, or nickel oxide. In one embodiment, the first p/n-type oxide material layer 110 and the second layer 112 comprise hafnium, titanium, or tantalum.

However, the first p/n-type oxide layer 110 and the second layer 112 will have opposite p/n-type doping. For example, if the first p/n-type oxide layer 110 is a p-type oxide layer, then the second layer 112 will be an n-type layer. Similarly, if the first p/n-type oxide layer 110 is an n-type oxide layer, then the second layer 112 will be a p-type layer. The first p/n-type oxide layer 110 and the second layer 112 have different p/n-types to form a p-n junction 120. The p-n junction 120 is formed at the interface between the first p/n-type oxide layer 110 and the second layer 112. The p-n junction 120 may equal the length of the second layer 112. The p-n junction 120 is formed to isolate the gate electrode 114. The p-n junction 120 conducts in one direction and blocks in the other direction.

One or more Schottky barriers are formed in the Schottky transistor memory device 100 by the combination of materials used in the source region 106, first p/n-type oxide layer 110, and drain region 108. A Schottky barrier creates a potential energy barrier for electrons formed at a conductive layer, a metal-semiconductor junction, or between two oxide layers. The source region 106 and the drain region 108 may be the metal half of the metal-semiconductor junction while the first p/n-type oxide layer 110 may act as the semiconductor half of the metal-semiconductor junction. Thus, a first Schottky barrier 116 may be formed at the interface between the source region 106 and the first p/n-type oxide layer 110, and a second Schottky barrier 118 may be formed at the interface between the drain region 108 and the first p/n-type oxide layer 110.

One Schottky barrier limits an electrical current in one direction while the other Schottky barrier limits a current in the opposite direction. The first Schottky barrier 116 may limit an electrical current in a forward direction and is conducting from the source region 106 to the drain region 108. The first Schottky barrier 116 is optional, and may not be present in the device 100. In one embodiment, the first Schottky barrier 116 is eliminated, such as by annealing. The second Schottky barrier 118 limits an electrical current in the opposite or reverse direction, isolating from the drain region 108 to the source region 106.

When two different resistive states are identified for a memory device (i.e., a high resistive state and a low resistive state), one state may be associated with a logic “zero,” while the other state may be associated with a logic “one” value. The combination of the second Schottky barrier 118 and the p-n junction 120 provides a high resistive state, or a non-conducting state, where current cannot flow. At zero voltage, the p-n junction 120 and the second Schottky barrier 118 prevent current from flowing between the gate electrode 114 and the drain region 108. As an electrical field or voltage is applied through the gate electrode 114, the second Schottky barrier 118 may be switched off and current may flow between the source region 106, the drain region 108, and the gate electrode 114. Utilizing the first p/n-type oxide layer 110 in between the source region 106 and the drain region 108 advantageously provides for filament formation.

FIG. 1B shows a schematic illustration of the Schottky transistor memory device 100 of FIG. 1A after applying voltage. The Schottky transistor memory device 100 may include the substrate 102, the insulating layer 104, the source region 106, the drain region 108, the first p/n-type oxide layer 110, the second layer 112, the gate electrode 114, the first Schottky barrier 116, the second Schottky barrier 118, the p-n junction 120, and a conductive anodic filament (CAF) 122. A voltage may be applied to the source region 106. By applying a gate voltage V_{G}, the breakdown voltage of the second Schottky barrier 118 is reduced, and simultaneously, the CAF 122 forms across the second Schottky barrier 118 from the first p/n-type oxide layer 110 to the drain region 108. The formation of the CAF 122 shorts the second Schottky barrier 118, bringing the device 100 to the low resistance state. The device 100 is non-volatile when in the low resistance state, and no voltage is required to maintain the low resistance state. Additionally, the CAF 122 remains even when the voltage is no longer applied. As long as the CAF 122 is in place, the device 100 operates in the low resistance state, regardless of the gate voltage. When two different resistive states are identified for a ReRAM device (i.e., a high resistive state and a low resistive state), one state may be associated with a logic “zero,” while the other state may be associated with a logic “one” value. As such, the formation of the CAF 122 across the second Schottky barrier 118 provides for a low resistive state, or a state associated with either 0 or 1.

FIG. 1C shows a schematic illustration of the Schottky transistor memory device 100 of FIG. 1B after a reverse voltage is applied. The Schottky transistor memory device 100 may include the substrate 102, the insulating layer 104, the source region 106, the drain region 108, the first p/n-type oxide layer 110, the second layer 112, the gate electrode 114, the first Schottky barrier 116, the second Schottky barrier 118, the p-n junction 120, and the CAF 122. To return the Schottky transistor memory device 100 to a high resistive state, a reverse voltage is applied to the drain region 108, and the second Schottky barrier 118 is restored. The reverse voltage breaks the CAF 122, and the second Schottky barrier 118 isolates the drain region 108 from the source region 106. The combination of the second Schottky barrier 118 and the p-n junction 120 again provides a high resistive state where current cannot flow, thus representing a state associated with either 0 or 1. A portion of the CAF 122 may still be present in the first p/n-type oxide layer 110. Reversing the polarity of the voltage makes the gate electrode 114 conductive, which may be utilized in readout circuitry to measure the state of the device 100.

A new filament may then be formed by applying voltage to the source region 106 and the gate electrode 114, like shown in FIG. 1B. Thus, CAF 122 formation can be controlled by the polarity of the voltage of the gate and the drain. The CAF 122 formation across the second Schottky barrier 118 advantageously provides for a low resistive state, whereas the CAF 122 breakage and the second Schottky barrier 118 restoration provide for a high resistive state. The two resistive states thus allow for a non-volatile memory device in a Schottky barrier field effect transistor. A separate transistor is not required for such a ReRAM device, advantageously resulting in a more cost-effective and compactly designed ReRAM device. Additionally, the non-volatile Schottky barrier field effect transistor is a very fast element with very low energy consumption. As such, the present disclosure may be used for ultra-low power non-volatile logic in IoT application, in-memory computation by combining logic and memory, and as a building block for non-volatile memory devices in 2D and 3D.

FIG. 1D shows a schematic illustration of a Schottky transistor device 140 according to another embodiment. Similar to FIGS. 1A-1C, the device 140 includes the substrate 102, the insulating layer 104, the source region 106, the drain region 108, the first p/n-type oxide layer 110, the gate electrode 114, the first Schottky barrier 116, and the second Schottky barrier 118. In the case of FIG. 1D, the second layer 112 has been replaced with a dielectric layer 130. As shown in FIG. 1D, the dielectric layer 130 is disposed not only over and in direct contact with the first layer 110, but also over and in contact with both the source region 106 and the drain region 108. It is to be understood that while the gate electrode 114 is shown to have a different width than the dielectric layer 130, the gate electrode 114 may have the same width as the dielectric layer 130 or a greater width than the dielectric layer 130. Suitable materials that may be used for the dielectric layer 130 include silicon dioxide, oxynitrides and high-k dielectric materials. The dielectric layer 130 comprises a non-conducting dielectric material.

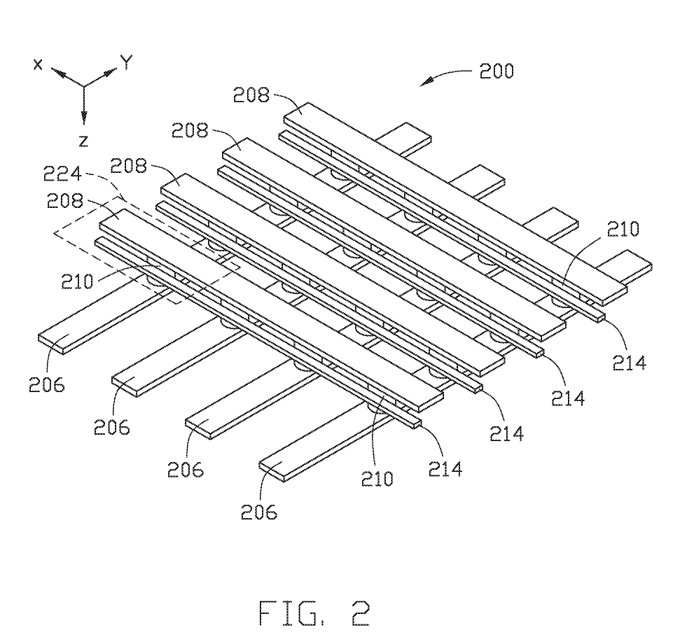

FIG. 2 shows a schematic illustration of a memory device array 200 including one or more Schottky transistor memory devices. The memory device array 200 may include one or more Schottky transistor devices similar to the Schottky transistor device 100 shown in FIGS. 1A-1C. In one embodiment, each device in the array 200 is a Schottky transistor memory device 100. The box labelled 224 represents one Schottky transistor memory device, such as the Schottky transistor memory device 100 shown in FIGS. 1A-1C. The memory device array 200 of FIG. 2 shows sixteen memory devices comprising the array, however, the memory device array 200 may be comprised of any number of memory devices. The memory device array 200 may include one or more source regions 206, one or more drain regions 208, one or more first p/n-type oxide layers 210, and one or more gate regions 214. The memory device array 200 may further include a second p/n-type oxide layer (or a dielectric layer), an insulating layer, and a substrate, none of which are shown. In the array 200, no two p/n-type oxide layers 210 share both a common source region 206 and a common drain region 208.

In the memory device array 200, the source regions 206 are longitudinally disposed in the x-direction. The drain regions 208 and the gate electrodes 214 are longitudinally disposed in the z-axis. The first p/n-type oxide layers 210 are longitudinally disposed in the y-axis. The source regions 206 are displaced from both the drain regions 208 and the gate electrodes 214 in the y-direction. While the gate electrodes 214 are in contact with the first p/n-type oxide layers 210, the gate electrodes 214 are not in contact with the source regions 206 or the drain regions 208. The first p/n-type oxide layers 210 are in contact with the source regions 206, the drain regions 208, and the gate electrodes 214. The source regions 206 are perpendicular to both the drain regions 208 and the gate electrodes 214. The drain regions 208 are parallel to the gate electrodes 214; however, the drain regions 208 are displaced from the gate electrodes 214 in the x-axis and the y-axis. A xyz-axis is included in FIG. 1A for clarity.

To select a single Schottky transistor memory device, such as the device in box 224, a voltage may be applied to the source region 206 and gate electrode 214 in contact with the desired first p/n-type oxide layer 210. By applying a voltage to both the gate electrode 214 and the source region 206, a CAF (not shown) forms across the first p/n-type oxide layer 210 to the drain region 208. The large voltage leads to the breakdown of the second Schottky barrier (not shown) and the formation of the CAF across the second Schottky barrier. After the formation of the CAF, the Schottky transistor memory device switches to a low resistance state representing a state associated with either 0 or 1. Reversing the polarity of the voltage breaks the CAF and restores the second Schottky barrier. Thus, the second Schottky barrier once again isolates the drain region 208 from the gate electrode 214 and the source region 206. The combination of the second Schottky barrier and the p-n junction again provides a high resistive state where current cannot flow, thus representing a state associated with either 0 or 1. Reversing the polarity of the voltage makes the gate electrode 214 conductive, which allows the array 200 to be utilized in readout circuitry in order to measure the state of each device in the array 200.

The three terminal ReRAM device having a Schottky barrier and a p-n junction switches from a low resistive state to a high resistive state using the conductive anodic filament, resulting in a non-volatile field effect transistor. The CAF short-circuits the reverse-biased barrier, maintaining the device in a low resistance state. Removing the CAF by reversing the polarity of the voltage switches the device back to a high resistance state. Reversing the polarity of the voltage makes the gate conductive, allowing for the memory state of the device to be read through the gate. Thus, the Schottky transistor memory device advantageously combines computation and memory by having a three terminal structure that is able to switch electronic signals, retain information when the power is turned off, and have the state of the device readout through the gate.

While the foregoing is directed to embodiments of the present disclosure, other and further embodiments of the disclosure may be devised without departing from the basic scope thereof, and the scope thereof is determined by the claims that follow.

1. A Schottky transistor memory device, comprising:
an insulating layer;
a source region disposed on the insulating layer;
a drain region disposed on the insulating layer;
a first oxide material layer disposed on the insulating layer in contact with the source region and the drain region;
a second layer disposed on the first oxide material layer; and
a gate electrode disposed on the second layer, wherein the first oxide material layer and the second layer form one of a p-n junction and a n-p junction.

2. The device of claim 1, wherein the second layer is selected from the group consisting of a second p-type or n-type material layer.

3. The device of claim 1, wherein the first oxide material layer is a p-type oxide material layer, and the second layer is an n-type oxide material layer.

4. The device of claim 1, wherein the first oxide material layer is an n-type oxide material layer, and the second layer is a p-type oxide material layer.

5. The device of claim 1, wherein the first oxide material-layer and the second layer comprise hafnium, titanium, or tantalum.

6. The device of claim 1, wherein the drain region comprises platinum, ruthenium, or nickel.

7. The device of claim 1, wherein an interface between the first oxide material layer and the drain region forms a Schottky barrier.

8. The device of claim 1, wherein an interface between the first oxide material layer and the source region forms a Schottky barrier.

9. (canceled)

10. A Schottky transistor memory device, comprising:
an insulating layer;
a source region disposed on the insulating layer;
a drain region disposed on the insulating layer;
a first p-type or n-type oxide material layer disposed on the insulating layer in between the source region and the drain region;
a second layer disposed on the first p-type or n-type oxide material layer;
a gate electrode disposed on the second layer; and
a conductive anodic filament extending from the drain region to the first p-type or n-type oxide material layer.

11. The device of claim 10, wherein the second layer is selected from the group consisting of a dielectric layer and a second p-type or n-type material layer.

12. The device of claim 10, wherein the first p-type or n-type oxide material layer is a p-type oxide material layer, and the second layer is an n-type oxide material layer.

13. The device of claim 10, wherein the first p-type or n-type oxide material layer is an n-type oxide material layer, and the second layer is a p-type oxide material layer.

14. The device of claim 10, wherein the first p-type or n-type oxide material layer and the second layer comprise hafnium, titanium, or tantalum.

15. The device of claim 10, wherein the drain region comprises platinum, ruthenium, or nickel.

16. The device of claim 10, wherein an interface between the first p-type or n-type oxide material layer and the drain region forms a Schottky barrier.

17. The device of claim 10, wherein an interface between the first p-type or n-type oxide material layer and the source region forms a Schottky barrier.

18. The device of claim 10, wherein the second layer is a dielectric layer and the dielectric layer is disposed on and in contact with the first p-type or n-type oxide material layer, source region and drain region.

19. A memory array comprising one or more Schottky transistor memory devices, at least one of the devices comprising:
an insulating layer;
a source region disposed on the insulating layer;
a drain region disposed on the insulating layer;
a first p-type or n-type oxide material layer disposed on the insulating layer in between the source region and the drain region;
a second layer disposed on the first p-type or n-type oxide material layer;
a gate electrode disposed on the second layer; and
a conductive anodic filament extending from the drain region to the first p-type or n-type oxide material layer.

20. The memory array of claim 19, wherein the second layer is selected from the group consisting of a dielectric layer and a second p-type or n-type material layer.

21. The memory array of claim 19, wherein the first p-type or n-type oxide material layer is a p-type oxide material layer, and the second layer is an n-type oxide material layer.

22. The memory array of claim 19, wherein the first p-type or n-type oxide material layer is an n-type oxide material layer, and the second layer is a p-type oxide material layer.

23. The memory array of claim 19, wherein the first p-type or n-type oxide material layer and the second layer comprise hafnium, titanium, or tantalum.

24. The memory array of claim 19, wherein the drain region comprises platinum, ruthenium, or nickel.

25. The memory array of claim 19, wherein an interface between the first p-type or n-type oxide material layer and the drain region forms a Schottky barrier.

26. The memory array of claim 19, wherein an interface between the first p-type or n-type oxide material layer and the source region forms a Schottky barrier.

27. The memory array of claim 19, wherein the second layer is a dielectric layer and the dielectric layer is disposed on and in contact with the first p-type or n-type oxide material layer, source region and drain region.
